(19) United States
(12) Patent Application Publication
(10) Pub. No.: US 2010/0204960 A1
(43) Pub. Date: Aug. 12, 2010

(54) REMOTE FAULT DETECTION AND CONDITION MONITORING

(75) Inventors: Jeffrey Wayne Hagadone, Canton, GA (US); Gregory Paul Morgan, Ashevillle, NC (US)

Correspondence Address: MERCHANT & GOULD PC, P.O. BOX 2903, MINNEAPOLIS, MN, 55402-0903, US

(73) Assignee: Wireless Data Procurement, Cumming, GA (US)

(21) Appl. No.: 12/366,681

(22) Filed: Feb. 6, 2009

(51) Int. Cl. G06F 11/00; G01R 31/00; G08B 21/00

(52) U.S. Cl. 702/188; 324/537; 340/635

(57) ABSTRACT

Remote fault detection and condition monitoring may be provided. First, at least one electrical characteristic of at least one monitored device at a first location may be measured. Next, it may be determined whether the at least one measured electrical characteristic of the at least one device indicates that at least one alarm condition has been triggered. Then, in response to determining that the at least one measured electrical characteristic of the at least one device indicates that at least one alarm condition has been triggered, at least one alert associated with the at least one alarm condition may be provided.

### BACKGROUND

Remote fault detection and condition monitoring is a process for measuring conditions, comparing them to parameters, and sending alerts. In some situations, devices may be situated at a distant location that is difficult or inconvenient to access and/or monitor. For example, an electronic display sign may be located at some distance from a central location, such as a billboard over a store and/or office. Often, there is no way to know that a component (e.g. a lamp) of the display sign has failed without an in-person inspection. Furthermore, such an in-person inspection may not be able to determine whether components may be about to fail before the failure actually occurs. Thus, the conventional strategy is to perform periodic inspections of remotely located devices to determine whether any components have failed or are performing improperly. This often causes problems because the conventional strategy wastes time and manpower and does not anticipate future failures. For example, an electronic display sign may be out of order for some time before an inspection occurs.

### SUMMARY

Remote fault detection and monitoring may be provided. First, at least one electrical characteristic of at least one monitored device at a first location may be measured. Next, it may be determined whether the at least one measured electrical characteristic of the at least one device indicates that at least one alarm condition has been triggered. Then, in response to determining that the at least one measured electrical characteristic of the at least one device indicates that at least one at least one alarm condition has been triggered, at least one alert associated with the at least one alarm condition may be provided.

Both the foregoing general description and the following detailed description are examples, and should not be considered to restrict the invention's scope, as described and claimed. Further, features and/or variations may be provided in addition to those set forth herein. For example, embodiments of the invention may be directed to various feature combinations and sub-combinations described in the detailed description.

### BRIEF DESCRIPTION OF THE DRAWINGS

The accompanying drawings, which are incorporated in and constitute a part of this disclosure, illustrate various embodiments of the present invention. In the drawings:

FIG. 1 is a block diagram of a system for providing remote monitoring;

FIG. 2 is a block diagram showing central server 115 in more detail;

FIG. 3 is a flow chart of a method for providing remote fault detection and condition monitoring;

FIG. 4 is a screen shot of an alarm dashboard interface; and

FIG. 5 is a screen shot of a monitored location control interface.

### DETAILED DESCRIPTION

The following detailed description refers to the accompanying drawings. Wherever possible, the same reference numbers are used in the drawings and the following description to refer to the same or similar elements. While embodiments of the invention may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the invention. Instead, the proper scope of the invention is defined by the appended claims.

Remote fault detection and condition monitoring may be provided. Consistent with embodiments of the present invention, a sensor may be installed to monitor at least one condition at a location and transmit measurements to a central server. The central server may determine whether the measurements may satisfy an alarm condition and respond appropriately by issuing an alert and/or work order. Consistent with embodiments of the invention, a processing device (e.g. a hub) at the monitored location may store the sensor's measurements and determine whether an alarm condition has been met. The processing device at the monitored location may then issue an appropriate alert and/or transmit the measurement to the central server.

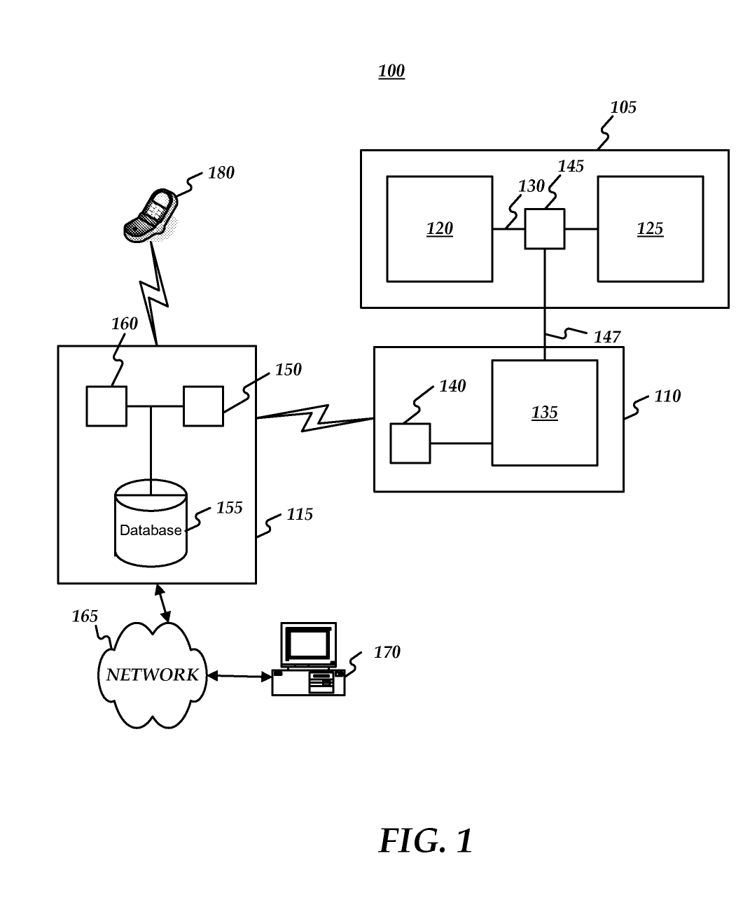

FIG. 1 is a block diagram of a system 100 for providing remote monitoring. System 100 may comprise a monitored device 105, a hub 110, and a central server 115. Monitored device 105 may comprise a power supply 120, a monitored component 125, and an electrical connection 130 for supplying power from power supply 120 to monitored component 125. Hub 110 may comprise a processing unit 135, a hub network component 140, and a sensor 145. Consistent with embodiments of the invention, sensor 145 may be physically located within hub 110 or outside hub 110. For example, sensor 145 may be attached to monitored device 105 and communicate with hub 110 via connection 147. Connection 147 may comprise a physical, wired connection and/or a wireless connection. Central server 115 may comprise a first server network component 150, a database 155, and a second server network component 160. System 100 may further comprise a network 165, a client 170, and a mobile device 180 (e.g. a laptop or cellular telephone).

Hub network component 140 may be operative to transmit and receive information over at least one data network. The at least one data network may use, but is not limited to, protocols such as cellular (e.g. GSM, CDMA, and TDMA), Wi-Fi, Ethernet, Bluetooth, a low power network such as a ZigBee® network as defined by the ZigBee® Alliance standard, or radio. Sensor 145 may be operative to monitor at least one characteristic associated with monitored device 105. For example, sensor 145 may be operable to measure an electrical characteristic such as power, current, voltage, or resistance of electrical connection 130.

Consistent with embodiments of the invention, sensor 145 may comprise, but is not limited to, a non-penetrating sensor, such as a current transducer, coupled around a wire comprising, for example, electrical connection 130. In other words, sensor 145 may sense a current in a wire (e.g. electrical connection 130) without having to penetrate the wire's insulation. Examples of non-penetrating current transducers may include AcuAmp™ ACT Series Current Transducers supplied by Automation Direct™ of Eden Prairie, Minn. Furthermore, sensor 145 may measure an environmental condition associated with monitored device 105, such as a light level around an ATM. In this embodiment, sensor 145 may comprise a photo resistor. Sensor 145 may not need to be connected to monitored device 105, but may measure a characteristic associated with the location of monitored device 105.

For example, monitored device 105 may comprise an electronic display sign, an automated teller machine (ATM), a billboard, a lamppost, and/or another electrically powered device. Monitored component 125 may comprise any piece of monitored device 105, such as a screen, a light bulb, an actuator, or a motor, for example. Hub 110 may communicate with central server 115 via hub network component 140. First server network component 150 may communicate via the same data network type as hub network component 140, and may be operative to translate data between multiple data network types. For example, hub network component 140 and first server network component 150 may communicate via a low power, ZigBee® network. Central server 115 may be operative to translate data received from hub 110 over the ZigBee® network for re-transmission over a cellular network from second server network component 150 to mobile device 180. Similarly, central server 115 may be operative to receive data from one network, translate the data for transmission on a third network, such as network 165, and send the data out to client 170 via the third network. Network 165 may comprise, for example, a wired Ethernet network, the Internet, or any other network.

Monitored device 105, for example, may comprise a front entrance sign for a retail store and monitored component 125 may comprise a light bulb. Sensor 145 may measure an amount of current drawn via electrical connection 130. Hub 110 may transmit the measured current back to central server 115. Central server 115 may be located inside the retail store and may comprise a computing device. Central server 115 may be operative to store the measured current, determine whether the measured current indicates that the light bulb has failed or is about to fail, and may provide an alarm to store personnel to repair or replace the light bulb.

For another example, monitored device 105 may comprise an automated teller machine (ATM) located at a bank branch and sensor 145 may comprise an ambient light sensor. Hub 110 may receive measurements from sensor 145 and determine when the ambient light level drops below a predetermined threshold. Hub 110 may then transmit the measured light level to central server 165 that may provide an alarm that the light around the ATM has dropped below an acceptable level, as from a loss of parking lot lighting, for example. Central server 115 may provide an alert (e.g. using Short Messaging Service (SMS)) to mobile device 180 and/or an e-mail alarm to client 170 via network 165. Consistent with embodiments of the invention, hub 11 0 may transmit every measurement taken to central server 115. Central server 115 may then make a determination whether the ambient light level has dropped below the predetermined threshold. Central server 115 need not be at the same or close location to hub 110. Consistent with embodiments of the invention, hub 110 may be operable to directly transmit measurements to an offsite receiver, such as by a cellular or a wired network connection.

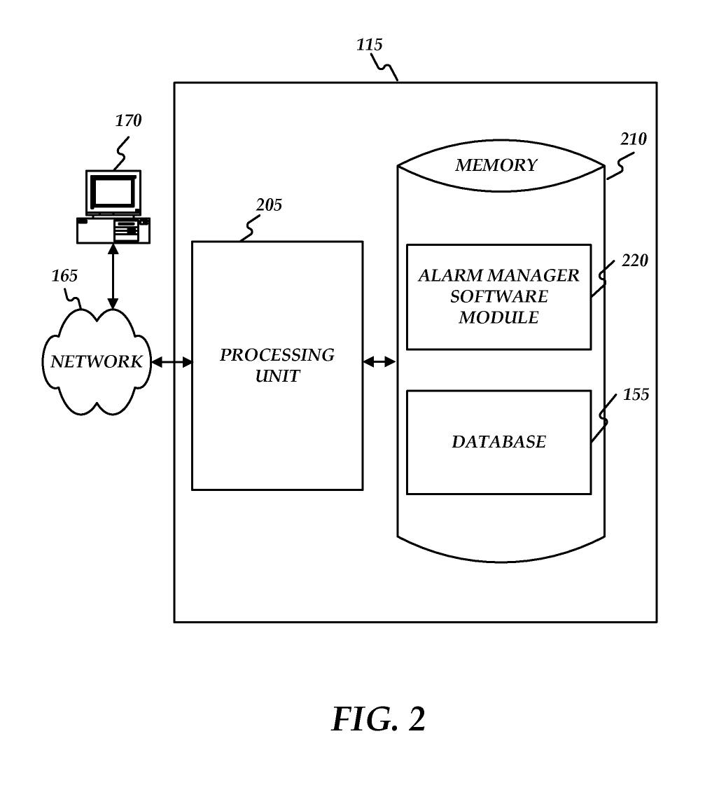

FIG. 2 is a block diagram showing central server 115 in more detail. Hub 110, client 170, and mobile device 180 may each comprise a construction similar to central server 115. As shown in FIG. 2, central server 115 may include a processing unit 205 and a memory 210. Memory 210 may include an alarm manager software module 220 and database 155. While executing on processing unit 205, alarm manager software module 220 may perform processes for receiving sensor measurements and/or sending alert messages, including, for example, one or more of method 300's stages described below with respect to FIG. 35. Any suitable combination of hardware, software, and/or firmware may be used to implement the memories, processing units, or other components. Consistent with embodiments of the invention, hub 11 0 and client 170 may comprise a similar structure and include software modules in addition to or instead of alarm manager software module 220.

Any of central server 115, hub 110, client 170, and mobile device 180 (i.e. “the processors”) included in system 100 may be implemented using a personal computer, network computer, mainframe, or other similar microcomputer-based device. The processors may comprise any type of computer operating environment, such as hand-held devices, multiprocessor systems, microprocessor-based or programmable sender electronic devices, minicomputers, mainframe computers, and the like. The processors may also be practiced in distributed computing environments where tasks are performed by remote processing devices. Furthermore, the processors may comprise a mobile terminal, such as a smart phone, a cellular telephone, a cellular telephone utilizing wireless application protocol (WAP), personal digital assistant (PDA), intelligent pager, portable computer, a hand held computer, a conventional telephone, or a facsimile machine. The aforementioned systems and devices are examples and the processors may comprise other systems or devices.

Network 165 may comprise, for example, a local area network (LAN) or a wide area network (WAN). When a LAN is used as network 165, a network interface located at any of the processors may be used to interconnect any of the processors. When network 165 is implemented in a WAN networking environment, such as the Internet, the processors may include an internal or external modem (not shown) or other means for establishing communications over the WAN. Further, in utilizing network 165, data sent over network 165 may be encrypted to insure data security by using encryption/decryption techniques.

In addition to utilizing a wire line communications system as network 165, a wireless communications system, or a combination of wire line and wireless may be utilized as network 165 in order to, for example, exchange web pages via the Internet, exchange e-mails via the Internet, or for utilizing other communications channels. Wireless can be defined as radio transmission via the airwaves. However, it may be appreciated that various other communication techniques can be used to provide wireless transmission, including infrared line of sight, cellular, microwave, satellite, packet radio, and spread spectrum radio. The processors in the wireless environment can be any mobile terminal, such as the mobile terminals described above. Wireless data may include, but is not limited to, paging, text messaging, e-mail, Internet access and other specialized data applications specifically excluding or including voice transmission. For example, the processors may communicate across a wireless interface such as, for example, a cellular interface (e.g., general packet radio system (GPRS), enhanced data rates for global evolution (EDGE), global system for mobile communications (GSM), code division multiple access (CDMA), long term evolution (LTE)), a wireless local area network interface (e.g., WLAN, IEEE 802), a Bluetooth interface, another RF communication interface, and/or an optical interface.

System 100 may also transmit data by methods and processes other than, or in combination with, network 165. These methods and processes may include, but are not limited to, transferring data via, diskette, flash memory sticks, CD ROM, facsimile, conventional mail, an interactive voice response system (IVR), or via voice over a publicly switched telephone network.

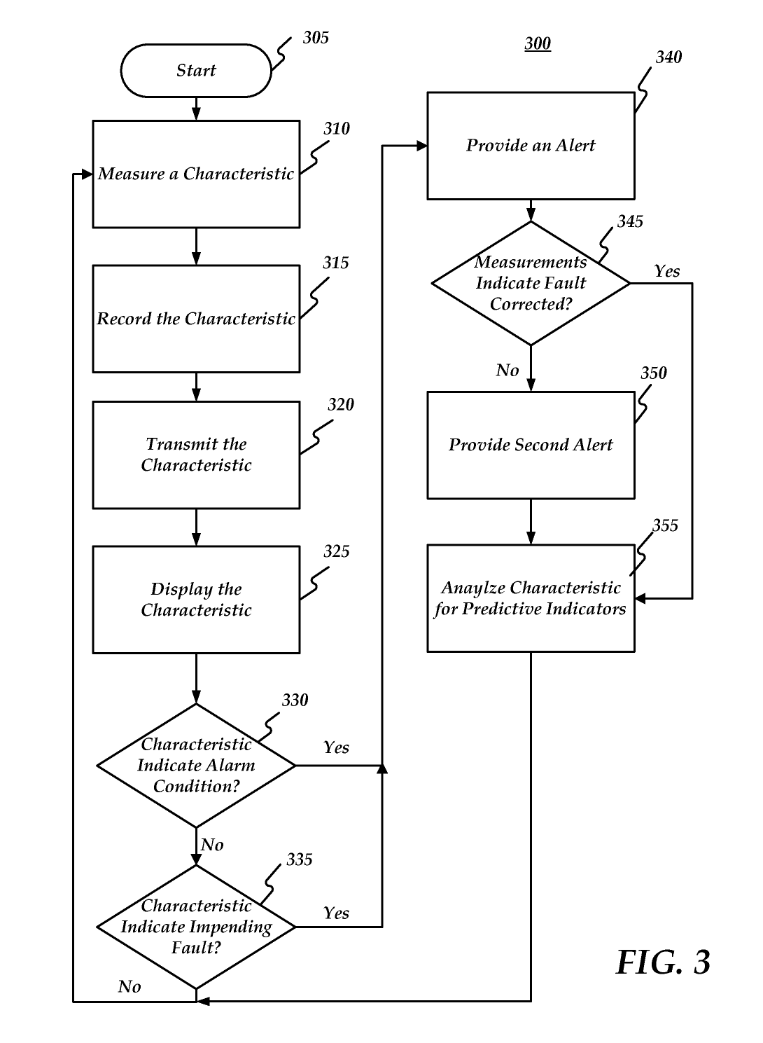

FIG. 3 is a flow chart setting forth the general stages involved in a method 300 consistent with an embodiment of the invention for providing remote fault detection and condition monitoring. Method 300 may be implemented using system 100 as described in more detail above with respect to FIG. 1. Ways to implement the stages of method 300 will be described in greater detail below.

Method 300 may begin at starting block 305 and proceed to stage 310 where hub 110 may measure a characteristic. For example, hub 110 may use sensor 145 to measure the characteristic of monitored device 105. Monitored device 105 may comprise, for example, an electronic display sign and sensor 145 may be operable to measure an electrical characteristic such as power (e.g. wattage), resistance, current, and/or voltage in order to determine whether a component, such as a lighting component, in monitored device 105 has failed or is in danger of imminent failure. Monitored lighting components may include, for example, a light-emitting diode (LED), a fluorescent bulb, a neon bulb, and/or an incandescent bulb. Consistent with embodiments of the invention, sensor 145 may be operable to measure a switch position and/or an environmental characteristic, such as an ambient light level and/or temperature or other weather characteristics.

From stage 310, where hub 110 measured the characteristic, method 300 may advance to stage 315 where hub 110 may record the characteristic. For example, hub 110 may comprise a computing device and may store the measured characteristic in a memory 210. Consistent with embodiments of the invention, the recorded characteristic may be associated with a location identifier specific to the monitored location and/or device.

Once hub 110 records the characteristic in stage 315, method 300 may continue to stage 320 where hub 110 may transmit the characteristic to central server 115. The transmission may include a location identifier associated with monitored device 105. Hub 110 may transmit the measured characteristic to central server 115 prior to or without first recording the measured characteristic. Central server 115 may record the characteristic, for example, in database 155.

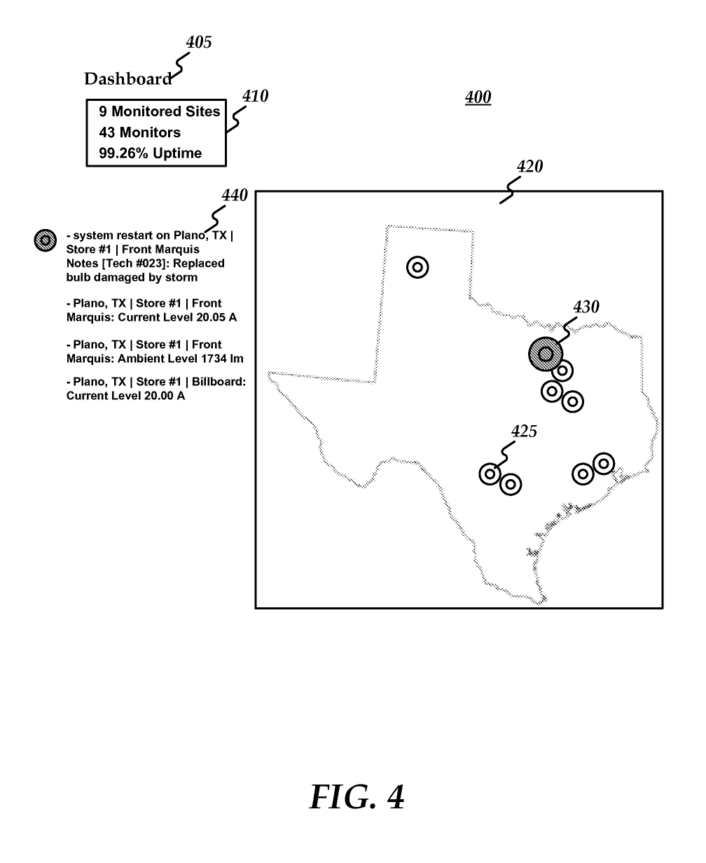

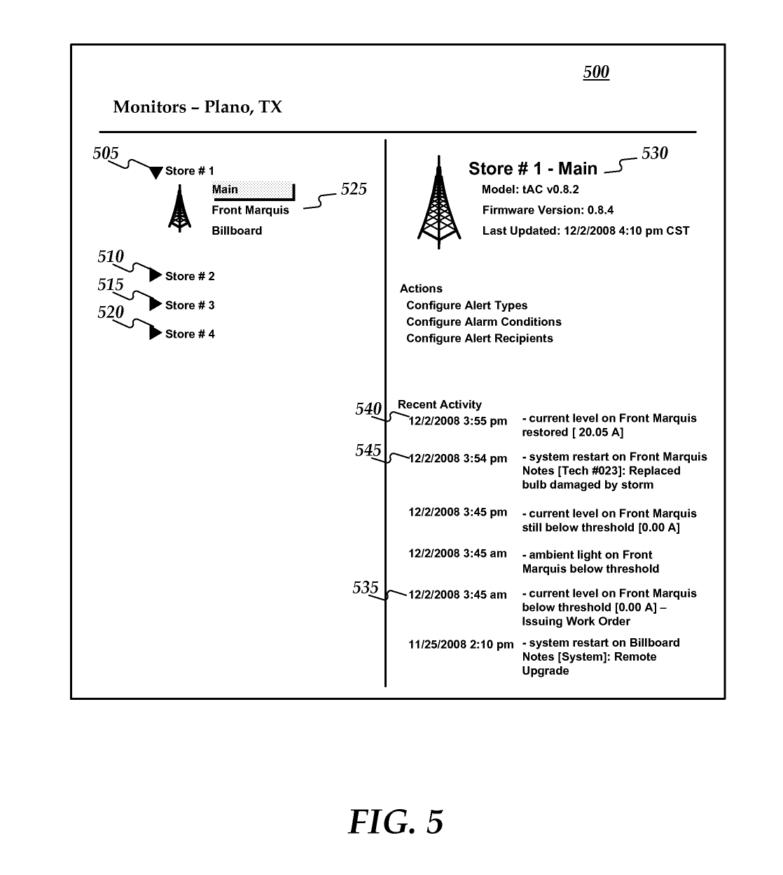

After hub 110 transmits the measured characteristic in stage 320 to central server 115, method 300 may proceed to stage 325 where central server 115 may display the measured characteristic. For example, central server 115 may display the measured characteristic in a user interface. The user interface may comprise a dashboard interface 400 and/or a control interface 500, described below with respect to FIGS. 4 and 5, respectively. The user interface may be provided via a display device associated with central server 115. Consistent with embodiments of the invention, the user interface may be provided via a web server and/or other network-based distribution to a remote display device. For example, the user interface may be accessible from a cell phone and/or from a plurality of computers other than central server 116.

The measured characteristic stored in database 155 may be accessible through reporting tools via the user interface. The reporting tools may be used to improve operational processes, customer service levels, and/or indicate quality and performance of hardware associated with monitored device 105. Central server 115 may also display previously received measurements. Consistent with embodiments of the invention, central server 115 may calculate statistics based on the measured characteristic and display the calculated statistics in the user interface. For example, central server 115 may calculate and display an average voltage measurement based on a received plurality of voltage measurements.

After central server 115 displays the measured characteristic, method 300 may proceed to stage 330 where central server 115 may determine whether the measured characteristic indicates an alarm condition. Conditions may comprise any comparison to and/or analysis of the measured characteristic. For example, an undercurrent alarm condition may be triggered if a current falls below a specified threshold. An overcurrent alarm condition may be triggered if a current is measured above a specified threshold. A deviation alarm condition may be triggered if the characteristic is measured at a specified value, if the characteristic is measured inside and/or outside a specified range, and/or if the characteristic differs from a calculated and/or specified average by a predetermined amount. Alarm conditions may also wait for the condition to occur more than a specified number of times and may further specify that the number of occurrences be within a specific time frame. For example, an alarm condition may require that an ambient light level sensor taking measurements every 30 seconds measure the light level below 300 lumens more than 3 times in a five minute period before triggering an alert.

If, at stage 330, central server 115 determines that the measured characteristic does not match an alarm condition, method 300 may proceed to stage 335 where central server 115 may determine whether the measured characteristic indicates that the monitored device has an impending fault, such as a component approaching failure. For example, central server 115 may determine whether a measured electrical characteristic is deviating from a nominal operational range, such as a steadily rising current on a lighting component indicating that the lighting component is about to burn out and fail. If at stage 335, central server 115 determines that the measured characteristic does not indicate an impending fault, method 300 may return to stage 310 where hub 110 may continue to measure and record the characteristic on a periodic basis.

Consistent with embodiments of the invention, each periodic measurement may be transmitted to central server 115 for storage and determination of any alarm conditions. Central server 115 may use the plurality of stored measurements to determine whether an alarm condition and/or impending fault is indicated, such as by calculating average measurements and analyzing deviations. For example, central server 115 may calculate an average current from a plurality of recorded current measurements. Central server 115 may then use the calculated average current to determine that a lighting component has begun drawing an amount of current over the calculated average and determine that this indicates an impending fault.

If, at stage 330 or 335, central server 115 determines that an alarm condition or an impending fault is indicated, method 300 may advance to stage 340 where central server 115 may provide an alert associated with the alarm condition and/or impending fault. The alert may comprise an email alert, an SMS alert, an audio indication such as an alert tone and/or recorded message, a visual indication, a web page update, a web feed (e.g. Atom and Really Simple Syndication (RSS)) update, and/or a work order. For example, in response to determining that a light bulb has failed on the monitored device, central server 115 may issue a work order to a service technician providing the location and/or directions to the monitored device, the time of failure, and/or a replacement part list.

After central server 115 provides the alert at stage 340, method 300 may proceed to stage 345 where central server 115 may receive another measurement of the characteristic and determine whether the measured characteristic indicates that the alarm condition and/or impending fault has been corrected. Consistent with embodiments of the invention, central server 115 may wait a specified period of time before making this determination. For example, central server 115 may determine whether the bulb has been replaced 24 hours after the measured characteristic indicated that a bulb had failed and a work order alert had been issued.

If, at stage 345, central server 115 determines that the alarm condition and/or impending fault has not been corrected, central server 115 may provide a second alert. Consistent with embodiments of the invention, the second alert may be of a different type than the first alert. For example, where the first alert may comprise a work order issued to a service technician, the second alert may comprise an email message sent to a service manager. Further consistent with embodiments of the invention, at stage 340 and 350, central server 115 may provide multiple alerts. For example, both the work order alert and the manager email may be noted in a web page update to a user interface such as dashboard interface 400 and/or control interface 500. Additionally, central server 115 may provide an alert when the indicated alarm condition and/or impending failure has been corrected. For example, central server 115 may provide an SMS alert to a location manager informing them that a burned out bulb has been replaced on the monitored device.

If, at stage 345, central server 115 determines that the indicated problem has been corrected, or after the second alert has been provided at stage 350, method 300 may advance to stage 355, where central server 115 may analyze the measured characteristic to try and determine an indication of impending fault. For example, if the measured characteristic indicated that a bulb had failed, central server 115 may analyze the measurements taken in a period approaching the failure to look for patterns. Detected indicators may be saved and compared to future measurements at stage 335 of method 300.

Data stored in database 155 may comprise information regarding the type of device and/or conditions being monitored. For example, database 155 may include component manufacturer information for each monitored device and/or component. Database 155 may store information associated with any corrections of alarm conditions, such as time to failure and the party responsible for correcting the problem. Analysis may determine a pattern in measurements associated with monitored device 105. For example, a particular brand of bulb may experience a current drop several times over a 24 hour period before the bulb fails. Similarly, another bulb type may experience a gradual increase in current drawn as the bulb approaches failure. Analysis may also determine whether a particular location, service provider, and/or a manufacturer experiences a higher rate of failure than another service provider, location, or manufacturer.

Once central server 115 has analyzed the measured characteristic for predictive indicators of failure in stage 355, method 300 may then return to stage 310 where hub 110 may continue to periodically measure the characteristic.

FIG. 4 is a screen shot of an alarm dashboard interface 400. Dashboard interface 400 may comprise a title 405, a statistics summary 410, and an overview graphic 420. Overview graphic 420 may comprise any displayed image such as a graph and/or map. For example, overview graphic 420 may comprise a map including icons representing monitored locations such as monitored location icon 425 and selected monitored location icon 430. Dashboard interface 400 may further comprise information 440 corresponding to selected monitored location icon 430, such as a summary of recent events, alerts, alarm conditions, measurements and/or messages.

Dashboard interface 400 may be customized for a particular user and/or client workstation. For example, a senior manager may be presented with summary information for all monitored locations while a service technician may be presented with alerts pertaining to an assigned service area.

Location icons such as monitored location icon 425 on dashboard interface 400 may be colored to indicate a status. For example, a green icon may indicate no current alarm condition, yellow may indicate an impending component failure, orange may indicate a current alarm condition, and red may indicate a current alarm condition that has not been corrected after a period of time such as 24 hours.

Overview graphic 420 may be scalable to display all and/or a subset of the presented information. For example, a default dashboard view may comprise a map of the United States and may allow a user to zoom in to a particular region, state, county, city, street, and/or neighborhood.

FIG. 5 is a screen shot of a monitored location control interface 500. Control interface 500 may be provided by central server 115 and/or a separate server with access to database 155 and may list any and/or all monitored locations. For example, control interface 500 may display monitored locations associated with a particular city, such as a first store 505, a second store 510, a third store 515, and a fourth store 520. Each monitored location may be expanded to provide a device display 525 of any and/or all monitored devices at the location. Each device listed in device display 525 may be selected and control interface 500 may provide an information display 530 associated with the selected device. Consistent with embodiments of the invention, information display 530 may also display information associated with any and/or all monitored devices at the selected location. For example, a user may select Piano, Texas, Store #1, Main to see information associated with all monitored devices at that particular store. Control interface 500 may also display a technician note 545 associated with the alarm condition. Information display 530 may also provide information on a particular controller and/or remote unit, such as a software and/or firmware version and when each hub and/or central server was last updated.

Information display 530 may comprise an interface for configuring characteristics to be monitored, alert types, alert recipients, and alarm conditions. Information display 530 may also provide a current measurement for at least one sensor and/or a list of recent activity associated with a monitoring hub measuring a characteristic of the selected device and/or location. Recent activity may comprise past and/or current measurements by a sensor, information entered by a user, triggered alarm conditions, and/or alerts sent. For example, information display 530 may show that an alarm condition occurrence 535, an alert (a work order, for example) was sent, and an alarm condition cessation 540. Control interface 500 may display patterns detected at stage 345 of method 300 and a history of previous measurements and/or alarm conditions in information display 530. Patterns may comprise, for example, a higher rate of failure among yellow bulbs than green bulbs at a selected location. Control interface 500 may also provide a report for a particular device and/or component that may rank manufacturers for the particular device/component.

Configuration changes made through information display 530 may be pushed to a selected monitored device over a communication network associated with central server 115 and hub 110. For example, hub 110 may monitor an ambient light level at an ATM. A user may update an alarm condition through information display 530 to send an SMS alert to a service depot when an ambient light level measured by sensor 145 drops below 1600 lumens rather than sending an e-mail alert when the ambient light level drops below 1700 lumens. Central server may send the updated information via first server network component 150 to hub 110, which may receive the update via hub network component 140. Consistent with embodiments of the invention, hub 110 may send all periodic measurements from sensor 145 to central server 115 and control interface 500 may be provided by client 170. Similarly, a user of client 170 may update an alert condition through control interface 500. Client 170 may then send the updated information to central server 115, which may be responsible for receiving the sensor measurements from hub 110, determining whether the sensor measurements trigger the updated alert condition, and sending an appropriate alert.

An embodiment consistent with the invention may comprise a system for providing remote fault detection and monitoring. The system may comprise a memory storage and a processing unit coupled to the memory storage. The processing unit may be operative to measure a characteristic, determine whether the measured characteristic indicates an alarm condition, and provide an alert associated with the alarm condition.

Another embodiment consistent with the invention may comprise a system for providing remote monitoring. The system may comprise a sensor, a transmitter, a monitor, and a receiving device comprising a memory storage, and a processing unit coupled to the processing unit. The processing unit may be operative to receive sensor measurements and a location identifier transmitted by the monitor, determine whether the measurements indicate an alarm condition, and provide an alert associated with the alarm condition. Consistent with embodiments of the invention, the system may be operative to receive measurements and location identifiers from a plurality of monitors.

Yet another embodiment consistent with the invention may comprise a device for providing remote fault detection and condition monitoring. The device may comprise a memory storage, a measurement component such as a sensor, a communication component such as a network communication card and/or antenna, and a processing unit coupled to the memory storage, the measurement component, and the communication component. The processing unit may be operative to receive conditions representing alarm conditions for which alerts should be provided, receive measurements of a characteristic, store the measurement, determine whether the measurement indicates an alarm condition, and provide an alert associated with the alarm condition.

Generally, consistent with embodiments of the invention, program modules may include routines, programs, components, data structures, and other types of structures that may perform particular tasks or that may implement particular abstract data types. Moreover, embodiments of the invention may be practiced with other computer system configurations, including hand-held devices, multiprocessor systems, microprocessor-based or programmable consumer electronics, minicomputers, mainframe computers, and the like. Embodiments of the invention may also be practiced in distributed computing environments where tasks are performed by remote processing devices that are linked through a communications network. In a distributed computing environment, program modules may be located in both local and remote memory storage devices.

Furthermore, embodiments of the invention may be practiced in an electrical circuit comprising discrete electronic elements, packaged or integrated electronic chips containing logic gates, a circuit utilizing a microprocessor, or on a single chip containing electronic elements or microprocessors. Embodiments of the invention may also be practiced using other technologies capable of performing logical operations such as, for example, AND, OR, and NOT, including but not limited to mechanical, optical, fluidic, and quantum technologies. In addition, embodiments of the invention may be practiced within a general purpose computer or in any other circuits or systems.

Embodiments of the invention, for example, may be implemented as a computer process (method), a computing system, or as an article of manufacture, such as a computer program product or computer readable media. The computer program product may be a computer storage media readable by a computer system and encoding a computer program of instructions for executing a computer process. The computer program product may also be a propagated signal on a carrier readable by a computing system and encoding a computer program of instructions for executing a computer process. Accordingly, the present invention may be embodied in hardware and/or in software (including firmware, resident software, micro-code, etc.). In other words, embodiments of the present invention may take the form of a computer program product on a computer-usable or computer-readable storage medium having computer-usable or computer-readable program code embodied in the medium for use by or in connection with an instruction execution system. A computer-usable or computer-readable medium may be any medium that can contain, store, communicate, propagate, or transport the program for use by or in connection with the instruction execution system, apparatus, or device.

The computer-usable or computer-readable medium may be, for example but not limited to, an electronic, magnetic, optical, electromagnetic, infrared, or semiconductor system, apparatus, device, or propagation medium. More specific computer-readable medium examples (a non-exhaustive list), the computer-readable medium may include the following: an electrical connection having one or more wires, a portable computer diskette, a random access memory (RAM), a read-only memory (ROM), an erasable programmable read-only memory (EPROM or Flash memory), an optical fiber, and a portable compact disc read-only memory (CD-ROM). Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory.

Embodiments of the present invention, for example, are described above with reference to block diagrams and/or operational illustrations of methods, systems, and computer program products according to embodiments of the invention. The functions/acts noted in the blocks may occur out of the order as shown in any flowchart. For example, two blocks shown in succession may in fact be executed substantially concurrently or the blocks may sometimes be executed in the reverse order, depending upon the functionality/acts involved.

While certain embodiments of the invention have been described, other embodiments may exist. Furthermore, although embodiments of the present invention have been described as being associated with data stored in memory and other storage mediums, data can also be stored on or read from other types of computer-readable media, such as secondary storage devices, like hard disks, floppy disks, or a CD-ROM, a carrier wave from the Internet, or other forms of RAM or ROM. Further, the disclosed methods' stages may be modified in any manner, including by reordering stages and/or inserting or deleting stages, without departing from the invention.

All rights including copyrights in the code included herein are vested in and the property of the Applicant. The Applicant retains and reserves all rights in the code included herein, and grants permission to reproduce the material only in connection with reproduction of the granted patent and for no other purpose.

While the specification includes examples, the invention's scope is indicated by the following claims. Furthermore, while the specification has been described in language specific to structural features and/or methodological acts, the claims are not limited to the features or acts described above. Rather, the specific features and acts described above are disclosed as example for embodiments of the invention.

What is claimed is:

1. A method for providing remote fault detection and monitoring, the method comprising:
measuring at least one electrical characteristic of at least one monitored device at a first location;
determining whether the at least one measured electrical characteristic of the at least one device indicates that at least one alarm condition has been triggered; and
in response to determining that the at least one measured electrical characteristic of the at least one device indicates that at least one alarm condition has been triggered, providing at least one alert associated with the at least one alarm condition.

2. The method of claim 1, further comprising:
transmitting the measured at least one electrical characteristic to at least one central server at a second location;
recording the measured at least one electrical characteristic by the at least one central server; and
providing a user interface by the at least one central server for displaying the measured at least one electrical characteristic.

3. The method of claim 1, wherein the electrical characteristic comprises at least one of the following: a power measurement, a resistance measurement, a current measurement, and a voltage measurement.

4. The method of claim 1, wherein the at least one alarm condition comprises a failure of at least one lighting component.

5. The method of claim 4, wherein the lighting component comprises at least one of the following: a light-emitting diode, a fluorescent bulb, a neon bulb, and an incandescent bulb.

6. The method of claim 1, further comprising:
measuring the at least one electrical characteristic of the at least one device periodically; and
recording a plurality of the periodic measurements of the at least one electrical characteristic.

7. The method of claim 6, further comprising:
determining whether the plurality of recorded measurements indicate that at least one component of the at least one device is approaching failure; and
in response to determining that the plurality of recorded measurements indicate that the at least one component is approaching failure, providing at least one alert associated with the approaching failure of the at least one component.

8. The method of claim 7, wherein determining whether the plurality of recorded measurements indicate that the at least one component is approaching failure comprises determining whether the at least one measured electrical characteristic is deviating from a nominal operational range by a first predetermined amount.

9. The method of claim 8, wherein determining whether the at least one measured electrical characteristic is deviating from a nominal operational range comprises determining whether a current drawn by the at least one component is exceeding an average current by a second predetermined amount.

10. The method of claim 9, wherein the average current is calculated from the plurality of recorded measurements.

11. The method of claim 6, further comprising:
analyzing the recorded measurements after the failure of the at least one component to determine at least one indication of approaching failure for the at least one component.

12. The method of claim 1, wherein measuring at least one electrical characteristic of at least one device comprises measuring a current from a non-penetrating sensor associated with at least one wire connected to the at least one device.

13. A system for providing remote monitoring, the system comprising:
a memory,
a server network component, and
a processing unit coupled to the memory storage and the first server network component, wherein the processing unit is operative to:
receive at least one measurement and at least one location identifier,
determine whether the at least one measurement indicates an alarm condition, and
in response to determining that the at least one measurement indicates an alarm condition, provide at least one first alert associated with the alarm condition.

14. The system of claim 13, wherein the processing unit being operative to provide the at least one first alert associated with the alarm condition comprises the processing unit being operative to provide at least one of the following: an email alert, a short messaging service (SMS) alert, an audio indication, a visual indication, a web page update, a web feed update, and a work order.

15. The system of claim 13, wherein the processing unit is further operative to receive measurements and location identifiers from a plurality of locations, wherein each of the locations is associated with a distinct location identifier.

16. The system of claim 13, wherein the central server is further operative to:
receive at least one second measurement and location identifier from the monitor indicating that the alarm condition is still in effect; and
send at least one second alert associated with the alarm condition, wherein the at least one second alert comprises at least one of the following: a different type of alert than the at least one first alert and a different recipient than the at least one first alert.

17. The system of claim 13, wherein the sensor is operable to measure at least one of: an electrical characteristic, a switch condition, and an environmental characteristic.

18. The system of claim 13, further comprising:
at least one hub comprising at least one sensor and at least one transmitter, wherein the hub is operative to:
receive, from the sensor, the at least one measurement, and
transmit, via the transmitter, the at least one measurement and the location identifier to the processing unit.

19. The system of claim 13, wherein the processing unit is further operative to:
store the at least one measurement and the location identifier in a database, wherein the location identifier is associated with a monitored location;
calculate statistics associated with the monitored location; and
provide a user interface operable to:
display at least one previously received measurement,
display the calculated statistics associated with the monitored location,
display a status of the monitored location,
display an indication of whether the at least one alarm condition is still in effect,
configure at least one alarm condition,
configure at least one alert type, and
configure at least one alert recipient.

20. A device for providing remote fault detection and condition monitoring, the device comprising:
at least one sensor operable to measure an amount of current drawn by at least one lighting component connected to at least one wire without penetrating an insulation of the at least one wire;
at least one network component operable to send and receive data via at least one first network, wherein the at least one first network comprises at least one of the following: a wired data connection, a wireless network, a Bluetooth network, a cellular network, a low power network,and a radio network;
a memory; and
at least one processing unit operably connected to the at least one sensor, the memory, and the at least one network component, wherein the processing unit is operable to:
receive, via the network component, at least one condition comprising at least one of the following: an amount of current comprising an undercurrent alarm condition, an amount of current comprising an overcurrent alarm condition, a current range comprising a normal current condition, and a percentage difference from an average current comprising a deviation alarm condition,
receive at least one measurement from the at least one sensor,
store the at least one measurement in the memory,
determine whether the at least one measurement satisfies the at least one alarm condition, and
in response to determining that the at least one measurement satisfies the at least one alarm condition, transmit, via the network component, the at least one measurement and a location identifier to a central server.
